(19) United States
(12) Patent Application Publication
(10) Pub. No.: US 2006/0186892 A1
(43) Pub. Date: Aug. 24, 2006

(54) Open-phase detecting method and apparatus

(75) Inventors: Kazuhiko Hiramatsu, Kitakyushu-shi (JP); Hajime Takahashi, Kitakyushu-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: KABUSHIKI KAISHA YASKAWA DENKI, Kitakyushu-shi (JP)

(21) Appl. No.: 11/341,855

(22) Filed: Jan. 30, 2006

Related U.S. Application Data
(63) Continuation-in-part of application No. PCT/JP04/10407, filed on Jul. 22, 2004.

(30) Foreign Application Priority Data
Jul. 30, 2003 (JP) 2003-283061

(51) Int. Cl. G01R 31/00

(52) U.S. Cl. 324/500

(57) ABSTRACT

An open-phase detecting method wherein a simple hardware structure is used to achieve a reduced cost: the IRQ member is reduced to reduce the load on a CPU; the open phase detection is performed in two items, that is, a phase difference and a voltage sign to reduce the possibility of occurrence of erroneous detections; and any phase that is open can be also determined. In the method for detecting any open-phase of the power supply of a three-phase converter, a neutral point N1 is connected to a negative pole side bus N of the DC side output of the rectifying means; an end of the first resistor of each phase, which connects the first resistor to the second resistor of each phase, is connected to an AD converter via a high input impedance means of the respective phase to detect the voltage of the respective phase; the voltage of the respective phase is outputted to a CPU that serves as an open-phase detecting means; and an open phase is detected when the sings of two of the three line voltages determined based on the voltages of the respective phases are different from each other and a phase difference thereof exhibits a half-wave rectification waveform of 180°.

This application is a continuation-in-part of International Application No. PCT/JP2004/10407 filed on Jul. 22, 2004.

### FIELD OF THE INVENTION

The present invention relates to, for example, a method and an apparatus for detecting an open-phase of a power supply of a three-phase converter.

### BACKGROUND OF THE INVENTION

The following description sets forth the inventor's knowledge of related art and problems therein and should not be construed as an admission of knowledge in the prior art.

In a conventional method for detecting an open-phase of a power supply of a three phase converter, a logical signal created by comparing a pseudo neutral point of a three-phase AC power source with an input voltage thereof is inputted to a counter to detect the phase difference of each phase. When the phase difference exceeds a predetermined value, it is discriminated that there is an open phase.

FIG. 10 shows a conventional block diagram disclosed by a Japanese Unexamined Laid-open Patent Publication No. 2003-235154 (hereinafter referred to as a “Patent Document 1”). As shown in FIG. 10, the phases r, s and t of the three-phase AC power source are connected with each other via resistors 55-60 at a neutral point of a Y-connection which will be referred to as a pseudo neutral point N1. The respective voltages R1 and S1 of the r-phases and the s-phase with respect to the pseudo neutral point N1 are detected. The comparator 61(62) detects whether the voltage R1 (S1) exceeds the voltage of the pseudo neutral point N1, and outputs a logic signal R2(S2) as “1” when the comparator 61(62) detects that the voltage R1(S1) exceeds the voltage of the pseudo neutral point N1. The logic signals R2 and S2 are inputted into the gates GA1 and GA2 of the counters 64 and 65, respectively, in which each counter value is latched by the CPU 67 at the rising edge of the logic signal. To the input terminals of the counters 64 and 65, an oscillator 63 is connected, so that each counter 64 and 65 can always count the value. The counters 64 and 65 are connected to the CPU 67 via the buses 66 so that the latched values can be read out by the CPU 67. The logic signals R2 and S2 are also inputted into the IRQ1 and IRQ2 of the CPU 67, respectively. The rising edge of each logic signal R2 and S2 makes the CPU 67 interrupt, and the CPU 67 reads the latched values of the counters 64 and 65 in accordance with the interruptions to calculate the phase difference of the logic signals R2 and S2. The aforementioned “IRQ” denotes a port for requesting an interruption to the CPU 67.

In cases where an open-phase occurs at the r-phase, since the voltage R1 becomes the same potential as that of the pseudo neutral point N1, no change occurs in logic signal R2.

In cases where an open-phase occurs at the s-phase, the same thing as mentioned above occurs.

On the other hand, in cases where an open-phase occurs at the t-phase, since the relation between the r-phase and the s-phase becomes a single-phase, the phase difference between the R1-phase and the S1-phase becomes 180 degrees and the phase difference between the logic signal R2 and the logic signal S2 also becomes 180°.

As will be understood from the above, in a normal status, the phase difference between the logic signal R2 and the logic signal S2 is 120°. However, when an open-phase occurs in a three-phase AC power supply, the phase difference becomes 180°, or the output of the logic signal R2 or S2 corresponding to the open-phase becomes unchangeable.

Therefore, the CPU 67 monitors whether the phase difference of the logical signal R2 and the logical signal S2 has exceeded a predetermined value (the value set to the CPU 67 in advance) over 120°, or whether either R2 or S2 has not changed over a predetermined time period (the value set to the CPU 67 in advance) to detect an open-phase (see Patent Document 1).

Furthermore, conventional technique for providing a reliable open-phase detecting apparatus capable of assuredly detecting an open-phase in an AC generating system is disclosed by a Japanese Unexamined Laid-open Patent Publication No. H06-335154 (hereinafter referred to as “Patent Document 2”). According to Patent Document 2, this apparatus is provided with a voltage fluctuation amount detecting device that monitors a voltage of both ends of a filter capacitor, extracts the voltage in a period of an integral multiplication of frequency twice as much as the frequency of the AC passing through the wiring and detects the fluctuation amount of the voltage, and a control device that compares the output of the voltage fluctuation amount detecting device with a predetermined reference value to output a protect operation command to an inverter when it is discriminated that the output is an abnormal value. The apparatus is further provided with an effective current fluctuation amount detecting device which calculates an effective value of a phase current passing at the output terminal of the inverter by detecting the phase current, extracts this effective value in a period of an integral multiplication of frequency twice as much as the frequency of the AC passing through the wiring, and a control device which compares the output of this effective current fluctuation amount detecting device with a predetermined reference value to output a protect operation command to the inverter when it is discriminated that the output is an abnormal value (see FIG. 1 of Patent Document 2).

In the open-phase detecting method as disclosed by Patent Document 1, a means for creating a pseudo neutral point and counters for two phases are required. This makes the hard structure complicate, causing a cost up. Furthermore, since the open-phase is detected only by the phase difference, it cannot be denied that there is a possibility of occurrence of erroneous detections. In addition, using two IRQs causes an increased load on the CPU.

The description herein of advantages and disadvantages of various features, embodiments, methods, and apparatus disclosed in other publications is in no way intended to limit the present invention. Indeed, certain features of the invention may be capable of overcoming certain disadvantages, while still retaining some or all of the features, embodiments, methods, and apparatus disclosed therein.

### SUMMARY OF THE INVENTION

The preferred embodiments of the present invention have been developed in view of the above-mentioned and/or other problems in the related art. The preferred embodiments of the present invention can significantly improve upon existing methods and/or apparatuses.

Among other potential advantages, some embodiments can provide an open-phase detecting method capable of achieving a reduced cost by employing a simple hardware structure.

Among other potential advantages, some embodiments can provide an open-phase detecting method capable of reducing a load on a CPU by reducing the number of IRQs and reducing the possibility of occurrence of erroneous detections.

Among other potential advantages, some embodiments can provide an open-phase detecting method capable of specifying an open-phase.

Among other potential advantages, some embodiments can provide an open-phase detecting apparatus capable of achieving a reduced cost by employing a simple hardware structure.

Among other potential advantages, some embodiments can provide an open-phase detecting apparatus capable of reducing a load on a CPU by reducing the number of IRQs and reducing the possibility of occurrence of erroneous detections.

Among other potential advantages, some embodiments can provide an open-phase detecting apparatus capable of specifying an open-phase.

According to a first aspect of the present invention, a method for detecting an open-phase of a power supply of a three-phase converter including a rectifying means for converting a three-phase AC power supply into a DC power supply, wherein one ends of respective phases of the three-phase AC power supply are connected to one ends of respective first resistors for respective phases, the other ends of the first registers are connected to one ends of respective second resistors for respective phases, and the three other ends of the second resistors are connected to each other, a connecting portion of the three other ends of the second resistors constituting a neutral point of a Y-connection, characterized in that the neutral point is connected to a negative pole side bus of a DC side output of the rectifying means; the other ends of the first resistors for respective phases, which connects the respective first resistors to the respective second resistors, are connected to respective AD converters via respective high input impedance means for the respective phases to detect the voltages of respective phases; the voltages of respective phases are outputted to a CPU that serves as an open-phase detecting means; and an open phase is detected when sings of two of the three-phase line voltages determined based on the voltages of respective phases are different from each other and a phase difference thereof exhibits a half-wave rectification waveform of 180°.

It is preferable that the high input impedance means is a non-inverting amplifier circuit using an operational amplifier.

According to a second aspect of the present invention, an open-phase detecting apparatus, comprises a rectifying circuit for converting a three-phase AC power supply into a DC power supply; first resistors for respective phases, one ends of the first resistors being connected to respective phases of the power supply; second resistors for respective phases, one ends of the second resistors being connected to the other ends of the respective first resistors, the three other ends of the second resistors being connected to each other, wherein a connecting portion of the three other ends of the second resistors constitutes a neutral point of a Y-connection; high input impedance members for respective phases, each high input impedance member having an input terminal connected to the other end of each of the respective first resistors; AD converters for respective phases, each AD converter having an input terminal connected to an output terminal of each of the respective high input impedance members; and a CPU to which outputs of the two of the AD converters are inputted, the CPU serving as an open-phase detecting means. The neutral point of the Y-connection is connected to a negative pole side bus of a DC side output of the rectifying circuit, and the CPU discriminates that there is an open phase when the CPU detects that sings of two of the three-phase line voltages determined based on the voltages of the respective phases are different from each other and that a phase difference thereof exhibits a half-wave rectification waveform of 180°.

It is preferable that the high input impedance member is a non-inverting amplifier circuit using an operational amplifier.

According to the first aspect of the present invention, in a three-phase converter for converting a three-phase AC power supply into a DC power supply, it becomes possible to provide an open-phase detecting method capable of achieving a reduced cost by employing a simple hardware structure, reducing a load on a CPU by reducing the number of IRQs and reducing the possibility of occurrence of erroneous detections by detecting an open-phase from two items, i.e., a phase difference and a voltage sign, and specifying an open-phase.

According to the second aspect of the present invention, in a three-phase converter for converting a three-phase AC power supply into a DC power supply, it becomes possible to provide an open-phase detecting apparatus capable of achieving a reduced cost by employing a simple hardware structure, reducing a load on a CPU by reducing the number of IRQs and reducing the possibility of occurrence of erroneous detections by detecting an open-phase from two items, i.e., a phase difference and a voltage sign, and specifying an open-phase.

The above and/or other aspects, features and/or advantages of various embodiments will be further appreciated in view of the following description in conjunction with the accompanying figures. Various embodiments can include and/or exclude different aspects, features and/or advantages where applicable. In addition, various embodiments can combine one or more aspect or feature of other embodiments where applicable. The descriptions of aspects, features and/or advantages of particular embodiments should not be construed as limiting other embodiments or the claims.

### BRIEF DESCRIPTION OF THE DRAWINGS

The preferred embodiments of the present invention are shown by way of example, and not limitation, in the accompanying figures, in which:

FIG. 1 is a structural view showing an embodiment of an open-phase detecting apparatus for a three-phase AC power supply according to a method of the present invention;

FIG. 2 is a graph showing an AD input voltage in a normal status according to the method of the present invention;

FIG. 3 is a graph showing an AD input voltage in a t-phase-open status according to the method of the present invention;

FIG. 4 is a graph showing the power voltage in a normal status according to the method of the present invention;

FIG. 5 is a graph showing the power voltage in a t-phase-open status according to the method of the present invention;

FIG. 6 is a graph showing the line voltage in a normal status according to the method of the present invention;

FIG. 7 is a graph showing the line voltage in a t-phase-open status according to the method of the present invention;

FIG. 8 is a graph showing the voltage of the DC bus line N in a normal status according to the method of the present invention;

FIG. 9 is a graph showing the voltage of the DC bus line N in a t-phase-open status according to the method of the present invention; and

FIG. 10 is a structural view showing an open-phase detecting apparatus for a three-phase AC power supply according to a prior art.

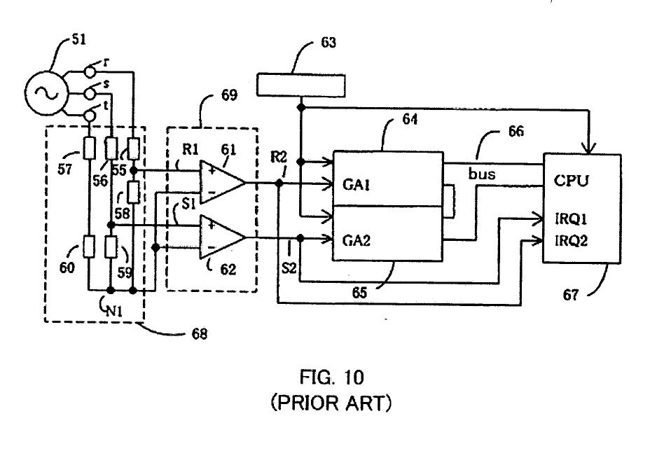

### DETAILED DESCRIPTION OF THE INVENTION

In the following paragraphs, some preferred embodiments of the invention will be described by way of example and not limitation. It should be understood based on this disclosure that various other modifications can be made by those in the art based on these illustrated embodiments.

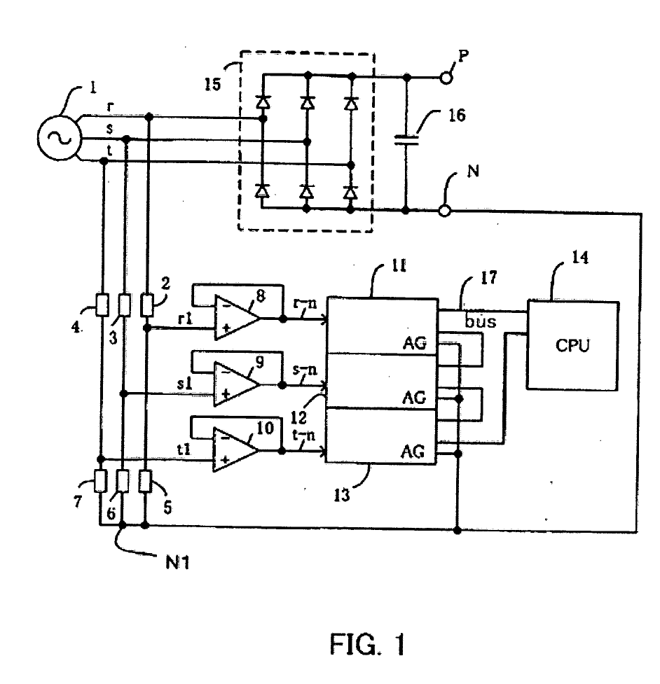

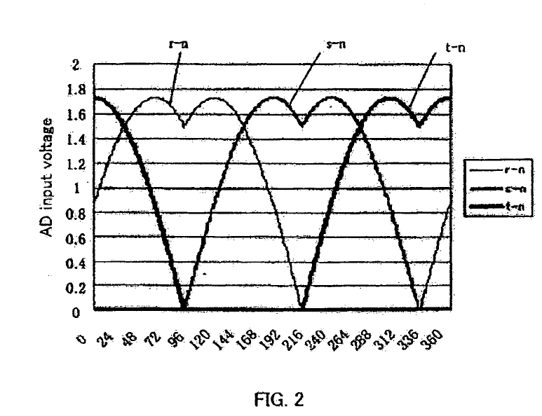

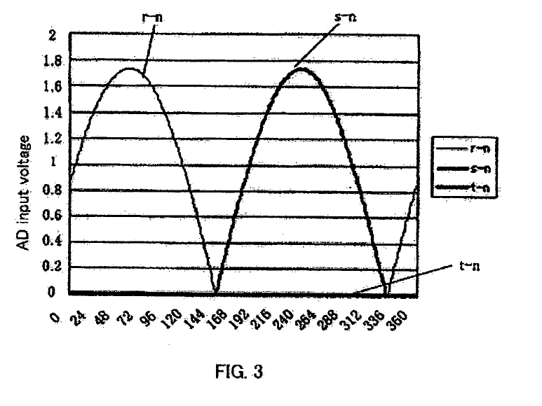

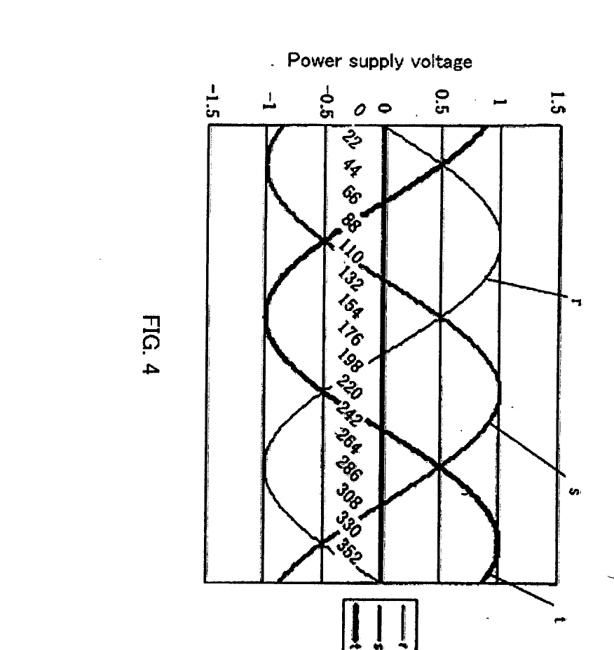

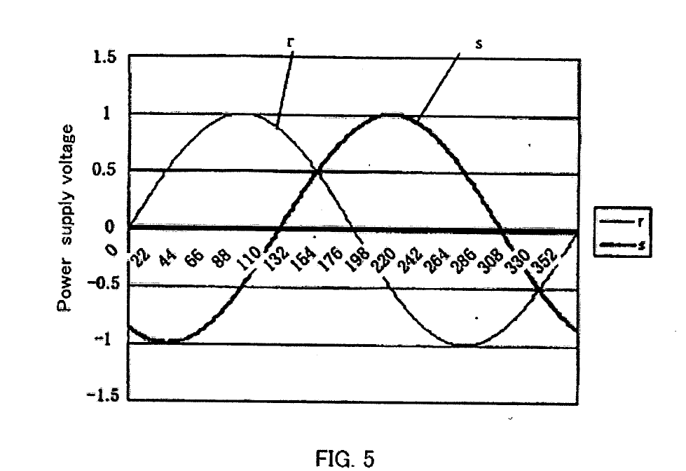

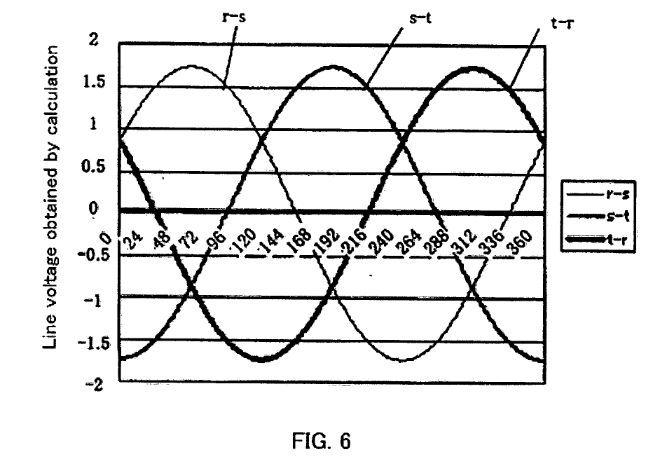

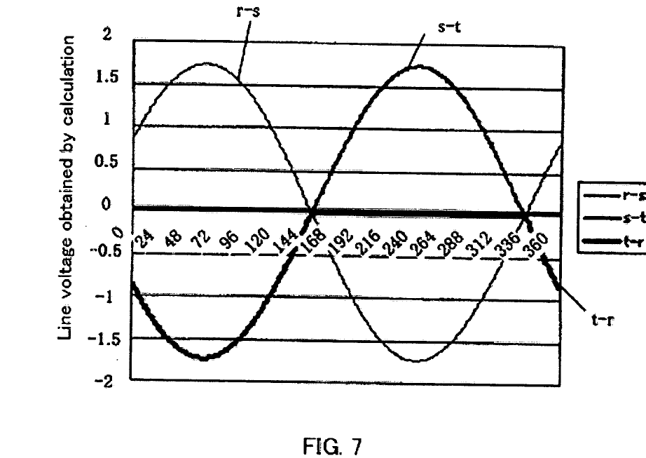

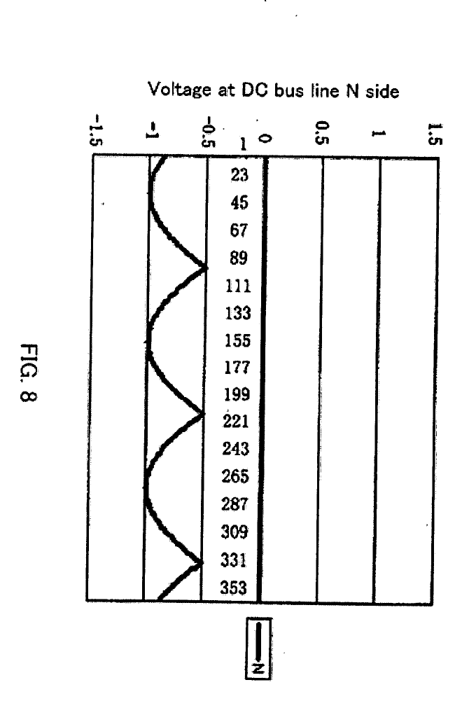

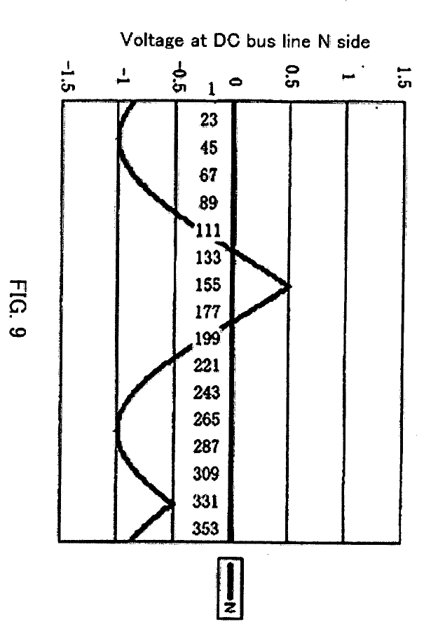

FIG. 1 shows an embodiment of a three-phase converter according to the method of the present invention, FIG. 2 shows the AD input voltage in a normal status, FIG. 3 shows the AD input voltage in a t-phase-open status, FIG. 4 is the power supply voltage in a normal status, FIG. 5 is the power supply voltage in a t-phase-open status, FIG. 6 shows the line voltage in a normal status, FIG. 7 is the line voltage in a t-phase-open status, FIG. 8 is the voltage of the DC bus line N in a normal status, and FIG. 9 is the voltage of the DC bus line N in a t-phase-open status.

In FIG. 1, the reference numeral “1” denotes a three-phase AC power supply, the reference numeral “2” denotes a first resistor for dividing the r-phase voltage, and the reference numeral “5” denotes a second resistor for dividing the r-phase voltage. In the same manner as in the r-phase, the s-phase voltage and the t-phase voltage are also divided by the first and second resistors 3 and 6 and the first and second resistors 4 and 7, respectively.

The reference numerals 8 to 10 denote an operational amplifier, respectively, the reference numerals 11 to 13 denote an AD converter, respectively, and the reference numeral 17 denotes a bus for connecting the AD converter with the CPU 14 for detecting an open-phase. The reference numeral “15” denotes a rectifying circuit for converting a three-phase AC voltage into a DC voltage, and the reference numeral “16” denotes a capacitor for smoothing the DC output voltage of the rectifying circuit 15. “P” denotes a positive pole side DC bus of the rectifying circuit 15 and “N” denotes a negative pole side bus thererof. The second resistors 5, 6 and 7 for respective phases are connected with each other at one end thereof to form a connecting point as a neutral point N1. This neutral point N1 is connected to the negative pole side DC bus N of the rectifying circuit 15.

The neutral point NI where the phases r, s and t of the three-phase AC power supply are connected each other via the resistors 2 to 7 into a Y-connection and the analog grounds AG of the AD converters 11 are connected to the negative pole side bus N which is an output of the three-phase diode bridge constituting the rectifying circuit 15. In order to detect the voltage r-n of the r-phase as seen from the negative pole side bus N, the voltage r1 obtained by dividing the r-phase voltage with the resistors 2 and 5 has to be inputted into the AD converter 11. When the r-phase voltage is directly inputted into the AD converter 11, however, the r-phase voltage will not be divided normally due to the low impedance of the AD converter 11, resulting in a failure of detecting the voltage. Accordingly, in order to attain high input impedance, a non-inverting amplifier circuit with one-time gain including the operational amplifier 8 as a high input impedance means is used. Thus, the voltage r-n is obtained. The obtained voltage is inputted into the AD converter 11.

As to the detection of the voltage s-n of the s-phase as seen from the negative pole side bus N and the detection of the voltage t-n of the t-phase as seen from the negative pole side bus N, in the same manner as explained above, the voltage s-n and the voltage t-n are obtained using the operational amplifiers 9 and 10, respectively, and the obtained voltage s-n and the voltage t-n are inputted into the AD converters 12 and 13, respectively.

Since the N side of the three-phase diode bridge is taken as a reference point, the voltage r-n, s-n, t-n on the basis of the minimum value of the three-phase power supply voltage as shown in FIG. 4 is appeared. In this state, the voltage of the DC negative pole side bus N is shown in FIG. 8, and the voltages r-n, s-n and t-n are shown in FIG. 2. This AD converted input voltage value is read by the CPU 14 via the bus 17. The CPU 14 calculates the difference between the values of two phases to obtain the sine wave line voltages r-s, s-t and t-r as shown in FIG. 6.

Now, it is assumed that the t-phase is open as an example. In this case, the power supply voltage to be inputted into the three-phase diode bridge becomes only the r-phase voltage and the s-phase voltage. At the DC negative pole side bus N, the minimum value of the power supply voltages of the r-phase and the s-phase will appear. The power supply voltage at this time is shown in FIG. 5 and the voltage of the DC negative pole side bus N is shown in FIG. 9. As a result, as the AD input voltages, half-wave rectification waveforms with a phase difference of 180° are appeared, the voltage t-n of the opened phase becomes nearly zero as shown in FIG. 3. The line voltages obtained from the differences of two phases become as shown in FIG. 7, and the line voltages of two phases t-r and s-t on the basis of the voltage t-n become half-wave rectification waveforms with different sign and 180° phase difference. In cases where another phase is open, in the same manner as explained above, the signs of two of the line voltages on the basis of the open-phase voltage become different with each other and the two of the line voltages exhibits a half-wave rectification waveform with a phase difference of 180°.

In the normal case, the phase difference of two of the line voltages obtained by the aforementioned method is 120°. However, when there is an open-phase, the signs of two of the line voltages on the basis of the open-phase voltage become different with each other and the two of the line voltages exhibits a half-wave rectification waveform with a phase difference of 180°. Accordingly, an open-phase can be detected by making the CPU 14 monitor that the signs of two of the three line voltages are different and the two of the line voltages exhibits a half-wave rectification waveform with a phase difference of 180°. Furthermore, it also becomes possible to specify the opened phase. For example, in the case shown in FIG. 7, since the line voltage r-s among the respective line voltages exhibits a sine wave, it is possible to judge that the remaining phase, i.e., the t-phase, is open.

The present invention can also be applied to detect the grounding since it detects a waveform distortion of a three-phase power supply.

While the present invention may be embodied in many different forms, a number of illustrative embodiments are described herein with the understanding that the present disclosure is to be considered as providing examples of the principles of the invention and such examples are not intended to limit the invention to preferred embodiments described herein and/or illustrated herein.

While illustrative embodiments of the invention have been described herein, the present invention is not limited to the various preferred embodiments described herein, but includes any and all embodiments having equivalent elements, modifications, omissions, combinations (e.g., of aspects across various embodiments), adaptations and/or alterations as would be appreciated by those in the art based on the present disclosure. The limitations in the claims are to be interpreted broadly based on the language employed in the claims and not limited to examples described in the present specification or during the prosecution of the application, which examples are to be construed as non-exclusive. For example, in the present disclosure, the term “preferably” is non-exclusive and means “preferably, but not limited to.”

In this disclosure and during the prosecution of this application, means-plus-function or step-plus-function limitations will only be employed where for a specific claim limitation all of the following conditions are present in that limitation: a) “means for” or “step for” is expressly recited; b) a corresponding function is expressly recited; and c) structure, material or acts that support that structure are not recited.

In this disclosure and during the prosecution of this application, the terminology “present invention” or “invention” may be used as a reference to one or more aspect within the present disclosure. The language present invention or invention should not be improperly interpreted as an identification of criticality, should not be improperly interpreted as applying across all aspects or embodiments (i.e., it should be understood that the present invention has a number of aspects and embodiments), and should not be improperly interpreted as limiting the scope of the application or claims. In this disclosure and during the prosecution of this application, the terminology “embodiment” can be used to describe any aspect, feature, process or step, any combination thereof, and/or any portion thereof, etc. In some examples, various embodiments may include overlapping features. In this disclosure and during the prosecution of this case, the following abbreviated terminology may be employed: “e.g.” which means “for example;” and “NB” which means “note well.”

We claim:

1. A method for detecting an open-phase of a power supply of a three-phase converter including a rectifying means for converting a three-phase AC power supply into a DC power supply, wherein one ends of respective phases of the three-phase AC power supply are connected to one ends of respective first resistors for respective phases, the other ends of the first registers are connected to one ends of respective second resistors for respective phases, and the three other ends of the second resistors are connected to each other, a connecting portion of the three other ends of the second resistors constituting a neutral point of a Y-connection, characterized in that
the neutral point is connected to a negative pole side bus of a DC side output of the rectifying means;
the other ends of the first resistors for respective phases, which connects the respective first resistors to the respective second resistors, are connected to respective AD converters via respective high input impedance means for the respective phases to detect the voltages of respective phases;
the voltages of respective phases are outputted to a CPU that serves as an open-phase detecting means; and
an open phase is detected when sings of two of the three-phase line voltages determined based on the voltages of respective phases are different from each other and a phase difference thereof exhibits a half-wave rectification waveform of 180°.

2. The method for detecting an open-phase of a power supply of a three-phase converter as recited in claim 1, wherein the high input impedance means is a non-inverting amplifier circuit using an operational amplifier.

3. An open-phase detecting apparatus, comprising:
a rectifying circuit for converting a three-phase AC power supply into a DC power supply;
first resistors for respective phases, one ends of the first resistors being connected to respective phases of the power supply;
second resistors for respective phases, one ends of the second resistors being connected to the other ends of the respective first resistors, the three other ends of the second resistors being connected to each other, wherein a connecting portion of the three other ends of the second resistors constitutes a neutral point of a Y-connection;
high input impedance members for respective phases, each high input impedance member having an input terminal connected to the other end of each of the respective first resistors;
AD converters for respective phases, each AD converter having an input terminal connected to an output terminal of each of the respective high input impedance members; and
a CPU to which outputs of the two of the AD converters are inputted, the CPU serving as an open-phase detecting means,
wherein the neutral point of the Y-connection is connected to a negative pole side bus of a DC side output of the rectifying circuit, and
wherein the CPU discriminates that there is an open phase when the CPU detects that sings of two of the three-phase line voltages determined based on the voltages of the respective phases are different from each other and that a phase difference thereof exhibits a half-wave rectification waveform of 180°.

4. The open-phase detecting apparatus as recited in claim 3, wherein the high input impedance means is a non-inverting amplifier circuit using an operational amplifier.
